(19) United States
(12) Patent Application Publication
(10) Pub. No.: US 2010/0109073 A1
(43) Pub. Date: May 6, 2010

(54) FLASH MEMORY DEVICE AND METHOD FOR MANUFACTURING THE SAME

(76) Inventor: Jin-Ha Park, Icheon-si (KR)

Correspondence Address: SHERR & VAUGHN, PLLC, 620 HERNDON PARKWAY, SUITE 320, HERNDON, VA, 20170, US

(21) Appl. No.: 12/604,665

(22) Filed: Oct. 23, 2009

(30) Foreign Application Priority Data
Nov. 6, 2008 (KR) 10-2008-0109757

(51) Int. Cl. H01L 29/792; H01L 21/28

(52) U.S. Cl. 257/324; 438/589; 438/591; 257/E29.309; 257/E21.21

(57) ABSTRACT

A flash memory device includes a semiconductor substrate having a trench formed therein, the trench including a device isolation film, an oxide film formed over the semiconductor substrate including the trench, a nitride film pattern inserted into the oxide film and formed at a sidewall of the trench, and a polysilicon pattern formed over the oxide film including the nitride film pattern. A method for manufacturing a flash memory device includes forming a first oxide film over the semiconductor substrate including the trench, forming the nitride film pattern at the sidewall of the trench provided with the first oxide film and forming a second oxide film over the semiconductor substrate including the nitride film pattern, forming an oxide film pattern at a contact surface between the nitride film pattern and the semiconductor substrate and a side of the nitride film pattern by partially removing the first oxide film and the second oxide film formed over the bottom of the trench and the semiconductor substrate, and forming a third oxide film over the semiconductor substrate including the oxide film pattern to form the oxide cover film into which the nitride film pattern is inserted.

The present application claims priority under 35 U.S.C. 119 to Korean Patent Application No. 10-2008-0109757 (filed on Nov. 6, 2008), which is hereby incorporated by reference in its entirety.

### BACKGROUND

A flash memory device is advantageous in that it is a nonvolatile memory that maintains data even without supplied power. A flash memory can promptly write, read, and erase the data. Because of these advantages, the flash memory device is widely used for the BIOS of personal computers, and data storage in set top boxes, printers and network servers. Recently, flash memory devices have also been incorporated into digital cameras and cellular phones.

An example of a flash memory device includes semiconductor devices based on a silicon-oxide-nitride-oxide-silicon (SONOS) structure. SONOS memory devices include channels formed in a horizontal direction.

### SUMMARY

Embodiments relate to a reliable flash memory device and a method for manufacturing the same, in which a SONOS structure is formed to facilitate program operation.

Embodiments relate to a flash memory device which includes a semiconductor substrate having a trench formed therein, the trench including a device isolation film, an oxide film formed over the semiconductor substrate including the trench, a nitride film pattern inserted into the oxide film and formed at a sidewall of the trench, and a polysilicon pattern formed over the oxide film including the nitride film pattern.

Embodiments relate to a method for manufacturing a flash memory device includes forming a first oxide film over the semiconductor substrate including the trench, forming the nitride film pattern at the sidewall of the trench provided with the first oxide film and forming a second oxide film over the semiconductor substrate including the nitride film pattern, forming an oxide film pattern at a contact surface between the nitride film pattern and the semiconductor substrate and a side of the nitride film pattern by partially removing the first oxide film and the second oxide film formed over the bottom of the trench and the semiconductor substrate, and forming a third oxide film over the semiconductor substrate including the oxide film pattern to form the oxide cover film into which the nitride film pattern is inserted.

The flash memory device and the method for manufacturing the same according to embodiments have the following advantages. In the SONOS structure, the first nitride film pattern is parallel with the sidewall of the trench and vertical to the semiconductor substrate. Accordingly, the SONOS structure is advantageous in that it does not affect the length of the gate and facilitates shrinkage of a memory cell. In addition, since the first nitride film pattern is vertical to the semiconductor substrate, it facilitates a program operation of the memory cell.

### DRAWINGS

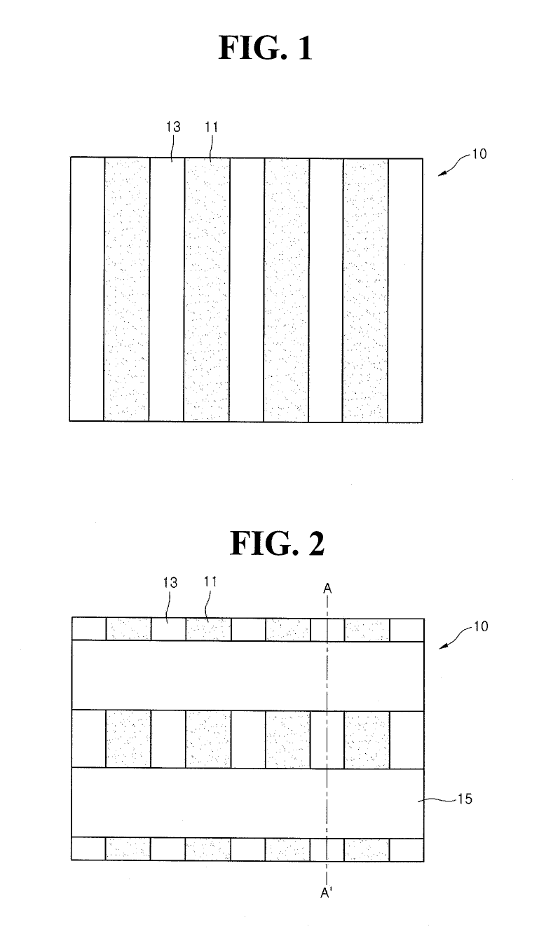

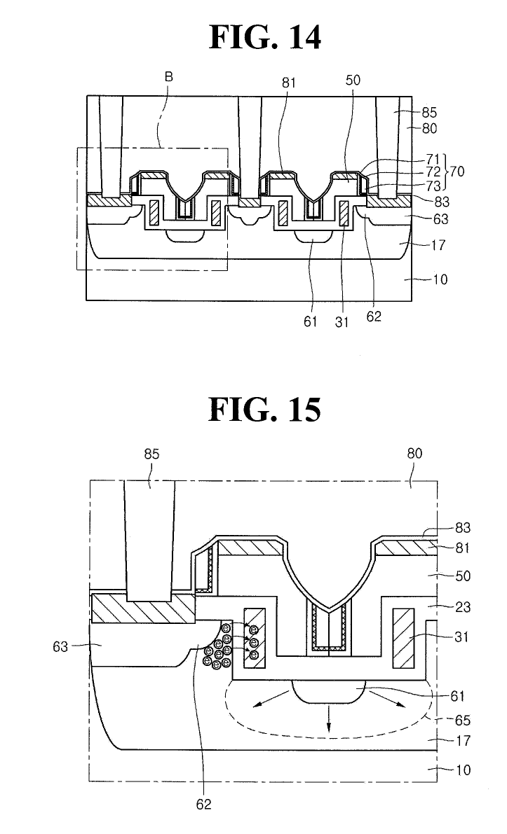

Example FIG. 1 to example FIG. 14 are process plane views and sectional views illustrating a flash memory device according to embodiments.

Example FIG. 15 to example FIG. 17 illustrate a region B shown in example FIG. 14 and program, erase and read operations.

### DESCRIPTION

Example FIG. 1 to example FIG. 14 are process plane views and sectional views illustrating a flash memory device according to embodiments. First of all, as shown in example FIG. 1, a device isolation film 11 may be formed in a semiconductor substrate 10 to define an active area 13.

As shown in example FIG. 2, a trench 15 may be formed in the semiconductor substrate 10 in which the active area 13 is defined. The trench 15 may be formed to cross the device isolation film 11 and the active area 13 formed in the semiconductor substrate 10.

A first ion injection process may be performed for the semiconductor substrate 10 to form a first impurity area 17 on the semiconductor substrate 10 including the trench 15. The first impurity area 17 may serve as a well area. Hereinafter, a method for manufacturing a flash memory device will be described with reference to a process according to a sectional view taken along line A-A′ of example FIG. 2.

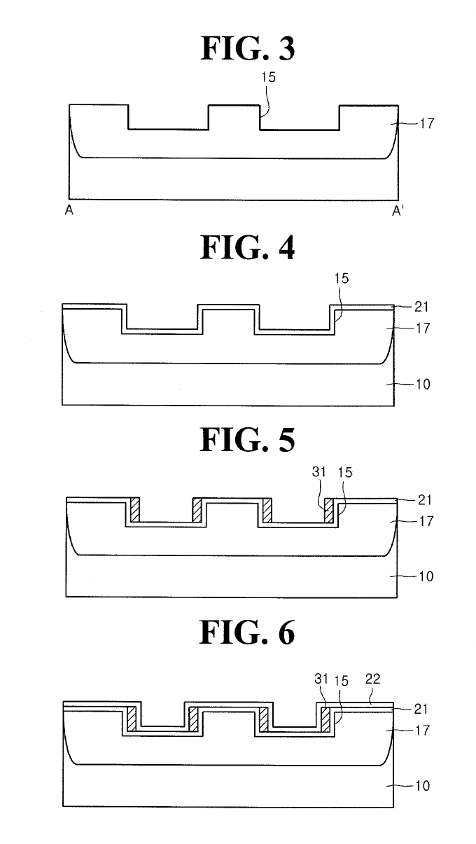

Example FIG. 3 is a sectional view of line A-A′ of example FIG. 2, and illustrates that the first impurity area 17 is formed on the semiconductor substrate 10 including the trench 15. The first impurity area 17 can be formed by injection of an n type dopant.

After the first impurity area 17 is formed, additional ion injection process for controlling a threshold voltage may be performed. In this case, the additional ion injection process for controlling a threshold voltage may be performed in such a manner that a p type dopant is tilt-injected into a sidewall area of the trench 15 on the semiconductor substrate 10. This forms a channel at the sidewall of the trench 15 on the semiconductor substrate 10 as a nitride film pattern is formed at the sidewall of the trench 15 to trap electrons.

As shown in example FIG. 4, a first oxide film 21 may be formed over the semiconductor substrate 10 on which the first impurity area 17 is formed. The first oxide film 21 can be formed by performing a first thermal process for the semiconductor substrate 10.

Subsequently, as shown in example FIG. 5, a first nitride film pattern 31 may be formed at the sidewall of the trench 15 over which the first oxide film 21 is formed. The first nitride film pattern 31 can be formed at the sidewall of the trench 15 by a first etching process after the first nitride film is formed over the semiconductor substrate 10 including the first oxide film 21.

The first etching process may an anisotropic etching process. At this time, the first nitride film pattern 31 may be formed parallel with the sidewall of the trench 15. Namely, the first nitride film pattern 31 may be formed parallel with the sidewall of the trench 15 and vertically with respect to the bottom of the trench 15. The length and thickness of the first nitride film pattern 31 can be controlled depending on the depth of the trench 15.

As shown in example FIG. 6, a second oxide film 22 may be formed over the semiconductor substrate 10 including the first nitride film pattern 31. The second oxide film 22 can be deposited by a low pressure chemical vapor deposition (LPCVD) process.

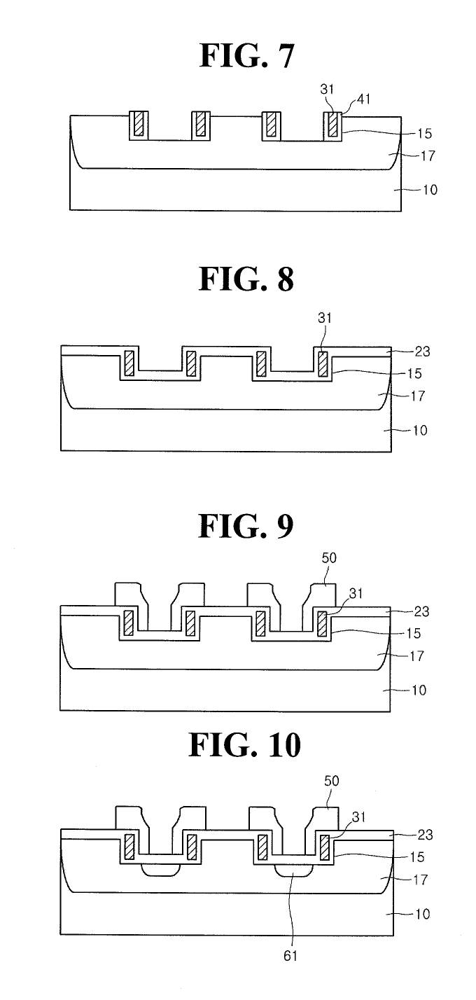

Subsequently, as shown in example FIG. 7, a second etching process is performed on the semiconductor substrate 10 including the second oxide film 22 to partially remove the first oxide film 21 and the second oxide film 22 formed over the semiconductor substrate.

The second etching process may be an anisotropic etching process, whereby a first oxide film pattern 41 remains at the sidewall of the trench 15 on the semiconductor substrate 10 to surround the first nitride film pattern 31. In other words, only the oxide film formed between the first nitride film pattern 31 and the semiconductor substrate 10 and the oxide film formed at the sidewall of the first nitride film pattern 31 remain, whereby an upper portion of first nitride film pattern 31 may be exposed, and a lower portion of first nitride film pattern 31 is inserted into the first oxide film pattern 41.

As shown in example FIG. 8, a second thermal process may be performed for the semiconductor substrate 10 including the first nitride film pattern 31 inserted into the first oxide film pattern 41, so as to form a third oxide film 23 over the first nitride film pattern 31. Since a defect of the device occurs due to damage caused by the first etching process for forming the first nitride film pattern 31, in order to improve reliability of the device, the third oxide film 23 may be formed after the first oxide film 21 is partially removed.

As the oxide film is formed over the exposed area of the first nitride film pattern 31 and the exposed area of the semiconductor substrate 10 by the second thermal process, the third oxide film 23 is formed to fully cover the first nitride film pattern 31. The third oxide film 23 will form an oxide-nitride-oxide (ONO) structure from a silicon-oxide-nitride-oxide-silicon (SONOS) structure. The third oxide film 23 may be formed of SiO₂ while the first nitride film pattern 31 may be formed of SiN.

Subsequently, as shown in example FIG. 9, a gate 50 of polysilicon is formed over the semiconductor substrate 10. The gate 50 may cover the sidewall and corners of the trench 15. One side of the gate 50 may be formed to adjoin the bottom of the trench 15. The gate 50 may be formed over first nitride film pattern 31, whereby two gates 50 can be formed in one trench 15. Also, since the two gates 50 formed in the trench 15 are spaced apart from each other, the third oxide film 23 may be exposed on the bottom of the trench 15.

As the gate 50 is formed, the SONOS structure of the semiconductor substrate 10, the third oxide film 23 including the first nitride film pattern 31, and the gate 50 may be formed. In the SONOS structure, the first nitride film pattern 31 may be parallel with the sidewall of the trench 15 and vertical to the semiconductor substrate 10. Accordingly, the SONOS structure is advantageous in that it does not affect a length of the gate and facilitates shrinkage of a memory cell. Also, since the first nitride film pattern 31 is vertical to the semiconductor substrate 10, it facilitates a programming operation of the memory cell.

In addition, in the SONOS structure, if the nitride film is parallel with the semiconductor substrate, electrons and holes may be inserted into different areas. However, in embodiments, the first nitride film pattern 31 may be vertical to the semiconductor substrate 10, so the electrons and the holes can be inserted to the same area. A gate of a peripheral circuit area may be formed after or when the gate 50 is formed.

As shown in example FIG. 10, a second ion injection process may be performed for the semiconductor substrate 10, whereby a second impurity area 61 may be formed on the semiconductor substrate 10 corresponding to the bottom of the trench 15. Since the second ion injection process may be performed on only the third oxide film 23 exposed on the bottom of the trench 15, the second impurity area 61 may be formed between the gates 50 on the bottom of the trench 15. The second ion injection process may be performed using arsenic or phosphorus ions. The second impurity area 61 may be used as a common source.

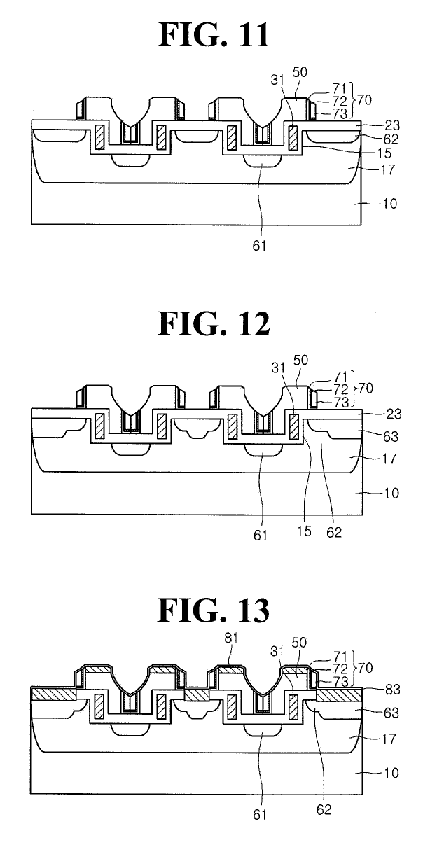

Subsequently, as shown in example FIG. 11, a third impurity area 62 corresponding to a lightly doped drain (LDD) area may be formed on the semiconductor substrate 10. A spacer 70 may be formed at the sidewall of the gate 50. The third impurity area 62 may be formed at the other side of the gate 50 provided with the second impurity area 61 at one side, and may be formed by a third ion injection process into the semiconductor substrate 10 between the gates 50.

A spacer 70 may be formed at the sidewall of the gate 50, and has an oxide-nitride-oxide (ONO) structure of a first spacer oxide film pattern 71, a spacer nitride film pattern 72, and a second spacer oxide film pattern 73.

In embodiments, the spacer 70 has, but not limited to, the ONO structure. For example, the spacer 70 may be formed with an oxide-nitride (ON) structure. The portion between the gates 50 adjoining the bottom of the trench 15 may be buried by the spacer 70. The bottom of the trench 15 located between the gates 50 may be covered with the spacer 70.

Subsequently, as shown in example FIG. 12, a fourth ion injection process may be performed using the spacer 70 and the gate 50 as masks to form a fourth impurity area 63 on the semiconductor substrate 10. The fourth impurity area 63 may be overlapped with the third impurity area 62, and is deeper than the third impurity area 62. The fourth ion injection process may be performed using arsenic or phosphorus ions.

For diffusion of the second impurity area 61, the third impurity area 62 and the fourth impurity area 63, a thermal process may additionally be performed between the respective processes. The second impurity area 61 may serve as a source area, and the fourth impurity area 63 may serve as a drain area.

As shown in example FIG. 13, a silicide layer 81 may be formed over the gate 50 and the fourth impurity area 63. A second nitride film 83 may be formed over the semiconductor substrate 83. The silicide layer 81 may be formed in such a manner that a salicide process is performed for the semiconductor substrate 10 using a material such as Co. The silicide layer 81 may be formed in an area where a contact will be formed. To form the silicide layer 81, the salicide process may be performed after the third oxide film 23 formed over the fourth impurity area 63 is partially removed. The second nitride film 83 is formed to protect a lower device, and can be formed of SiN.

Subsequently, as shown in example FIG. 14, an interlayer insulating film 80 may be formed over the semiconductor substrate 10. A contact 85 may be formed in the interlayer insulating film 80.

Example FIG. 15 to example FIG. 17 illustrate an area B shown in example FIG. 14, and program, erase and read operations. The program operation of the flash memory device according to embodiments may be performed by a Fowler-Nordheim (F-N) tunneling and hot carrier injection. The program operation according to F-N tunneling may be performed in such a manner that, if a high bias is applied to the gate 50 and a ground is applied to the source area corresponding to the second impurity area 61, the drain area corresponding to the fourth impurity area 63 and the semiconductor substrate 10, electrons from the semiconductor substrate 10 are trapped in the first nitride film pattern 35.

Example FIG. 15 illustrates the program operation of the flash memory device according to embodiments through hot carrier injection. As shown in example FIG. 15, if a sufficient bias is applied to the source area corresponding to the second impurity area 61, a depletion area 65 is extended to the area where the first nitride film pattern 31 is formed.

If a voltage is applied to the drain area corresponding to the fourth impurity area 63 when the bias is applied to the gate 50, electrons are liberated, whereby the electrons flowing to the source area corresponding to the second impurity area 61 are partially trapped in the first nitride film pattern 35. In this way, the program operation can be performed.

Subsequently, the erase operation of the flash memory device according to embodiments may be performed by F-N tunneling and hot carrier injection. The erase operation according to F-N tunneling may be performed in such a manner that a high bias is applied to the gate 50, the source area corresponding to the second impurity area 61 and the drain area corresponding to the fourth impurity area 63 are floated, and ground or positive (+) bias is applied to the semiconductor substrate 10.

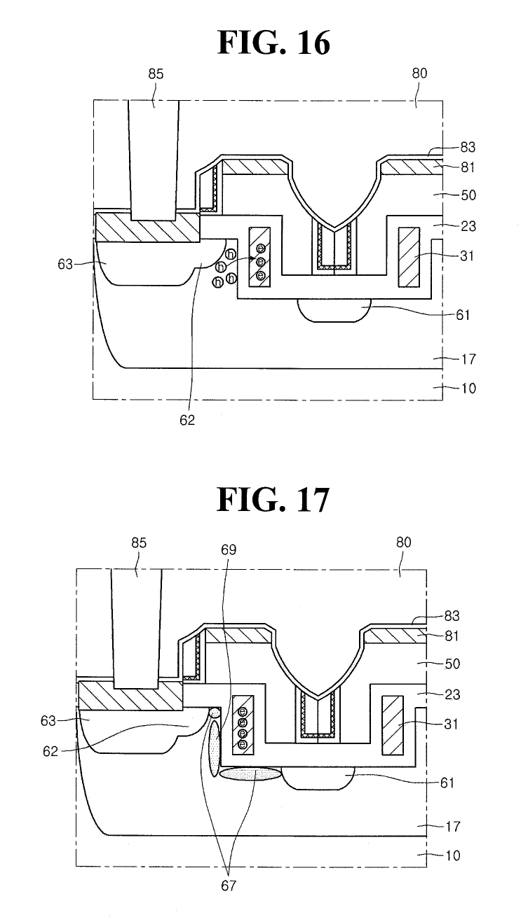

Example FIG. 16 illustrates the erase operation of the flash memory device according to embodiments through hot carrier injection. First of all, the source area corresponding to the second impurity area 61 may be allowed to float, the semiconductor substrate 10 is grounded, and a bias is applied to the drain area corresponding to the fourth impurity area 63 to form band to band tunneling (BTBT).

The erase operation may be performed in such a manner that a bias is applied to the drain area corresponding to the fourth impurity area 63 to form many electron-hole pairs (EHP), and negative (−) bias may be applied to the gate 50, whereby the holes formed by the EHP are trapped in the first nitride film pattern 35, as shown in example FIG. 16.

The read operation of the flash memory device according to embodiments may be performed with the source area corresponding to the second impurity area 61 grounded and a bias applied to the drain area corresponding to the fourth impurity area 63 and the gate 50, whereby the first area 67 is inverted.

At this time, a small current flows due to the electrons in a state that the flash memory device is programmed, while the bias applied to the gate 50 is transferred to a channel corresponding to a second area 69 to flow great current in a state that the flash memory device is erased. In other words, the size of the current during the program state is different from that of the current during the erase state. Accordingly, it is possible to identify whether the memory cell is in the program state or the erase state depending on the size of the current.

Also, since the channel area corresponding to the second area 69 is arranged between the first areas 67, even though over erase operation is performed for the second area 69, the first area 67 exists, whereby the current can flow to the second area 69. In other words, even though over erase operation is performed for the second area 69, no leakage current occurs in the channel area.

Example FIG. 17 is a side sectional view illustrating a flash memory device according to embodiments. The flash memory device according to embodiments includes a trench 15 formed in a semiconductor substrate 10 provided with a device isolation film, an oxide film 23 formed over the semiconductor substrate 10 including the trench 15, a nitride film pattern 31 inserted into the oxide film 23 and formed at a sidewall of the trench 15, and a gate 50 formed over the oxide film 23 including the nitride film pattern 31.

The nitride film pattern 31 may be formed parallel with the sidewall of the trench 15 and vertically to the bottom of the trench 15. The gate 50 may be formed over the bottom and corner areas of the trench 15 to cover the nitride film pattern 31.

The flash memory device further includes a first impurity area 61 formed on the bottom of the trench 15 at a side of the gate 50 on the semiconductor substrate 10, and a second impurity area 63 formed on the semiconductor substrate at the other side of the gate 50. The length and the thickness of the nitride film pattern 31 can be controlled depending on the depth of the trench 15.

The flash memory device and the method for manufacturing the same according to embodiments have the following advantages. In the SONOS structure, the first nitride film pattern is parallel with the sidewall of the trench and vertical to the semiconductor substrate. Accordingly, the SONOS structure is advantageous in that it does not affect the length of the gate and facilitates shrinkage of the memory cell. In addition, since the first nitride film pattern is vertical to the semiconductor substrate, it facilitates the program operation of the memory cell.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a semiconductor substrate having a trench formed therein, the trench including a device isolation film;
an oxide film formed over the semiconductor substrate including the trench;
a nitride film pattern inserted into the oxide film and formed at a sidewall of the trench; and
a polysilicon pattern formed over the oxide film including the nitride film pattern.

2. The apparatus of claim 1, wherein the nitride film pattern is formed parallel with the sidewall of the trench and vertically with respect to the bottom of the trench.

3. The apparatus of claim 1, wherein the polysilicon pattern is formed over the bottom and corner areas of the trench to cover the nitride film pattern.

4. The apparatus of claim 1, including:
a first impurity area formed on the bottom of the trench at a side of the polysilicon pattern on the semiconductor substrate; and
a second impurity area formed on the semiconductor substrate at the other side of the polysilicon pattern.

5. The apparatus of claim 1, wherein a length of the nitride film pattern is controlled depending on a depth of the trench.

6. The apparatus of claim 1, wherein a thickness of the nitride film pattern is controlled depending on a depth of the trench.

7. The apparatus of claim 1, wherein the trench is provided with two polysilicon patterns spaced apart from each other.

8. The apparatus of claim 1, wherein the substrate, trench, oxide film, nitride film pattern and polysilicon pattern form components in a flash memory cell.

9. A method comprising:
forming a trench in a semiconductor substrate provided with a device isolation film;
forming an oxide cover film over the semiconductor substrate including the trench, the oxide cover film including a nitride film pattern; and
forming a polysilicon pattern over the oxide cover film including the nitride film pattern,
wherein the nitride film pattern is inserted into the oxide cover film and formed at a sidewall of the trench.

10. The method of claim 9, wherein the step of forming an oxide film over the semiconductor substrate including the trench includes:
forming a first oxide film over the semiconductor substrate including the trench;
forming the nitride film pattern at the sidewall of the trench provided with the first oxide film and forming a second oxide film over the semiconductor substrate including the nitride film pattern;
forming an oxide film pattern at a contact surface between the nitride film pattern and the semiconductor substrate and a side of the nitride film pattern by partially removing the first oxide film and the second oxide film formed over the bottom of the trench and the semiconductor substrate; and
forming a third oxide film over the semiconductor substrate including the oxide film pattern to form the oxide cover film into which the nitride film pattern is inserted.

11. The method of claim 10, wherein the first oxide film is formed between the sidewall of the trench and the nitride film pattern when the nitride film pattern is formed at the sidewall of the trench.

12. The method of claim 10, wherein the first oxide film and the third oxide film are formed by a thermal process.

13. The method of claim 10, wherein the second oxide film is formed by a deposition process.

14. The method of claim 10, wherein the nitride film pattern is formed at the sidewall of the trench over the first oxide film by an anisotropic etching process after forming a nitride film over the first oxide film.

15. The method of claim 9, wherein the nitride film pattern is formed parallel with the sidewall of the trench and vertically with respect to the bottom of the trench.

16. The method of claim 9, wherein the polysilicon pattern is formed over the bottom and corner areas of the trench to cover the nitride film pattern.

17. The method of claim 9, wherein a length of the nitride film pattern is controlled depending on a depth of the trench.

18. The method of claim 9, wherein a thickness of the nitride film pattern is controlled depending on a depth of the trench.

19. The method of claim 9, wherein the trench is provided with two polysilicon patterns spaced apart from each other.

20. The method of claim 7, wherein the substrate, trench, oxide film, nitride film pattern and polysilicon pattern form components in a flash memory cell.
